(19) United States
(12) Patent Application Publication
(10) Pub. No.: US 2025/0338751 A1
(43) Pub. Date: Oct. 30, 2025

(54) DISPLAY PANEL AND DISPLAY DEVICE

(71) Applicants: Wuhan Tianma MicroElectronics Co., Ltd. Shanghai Branch, Shanghai (CN); Wuhan Tianma Micro-Electronics Co., Ltd., Wuhan (CN)

(72) Inventor: Mengying JIANG, Shanghai (CN)

(21) Appl. No.: 18/795,776

(22) Filed: Aug. 6, 2024

(30) Foreign Application Priority Data
Apr. 26, 2024 (CN) 202410519732.5

(51) Int. Cl. H10K 59/60; H10K 59/131; H10K 59/80

(52) U.S. Cl. CPC H10K 59/60; H10K 59/131; H10K 59/8792

(57) ABSTRACT

A display panel includes an array substrate, a light-emitting element, and a photoelectric element. The array substrate has a first driving circuit and a second driving circuit, arranged at intervals. The light-emitting element, on the array substrate, is arranged corresponding to the first driving circuit. The light-emitting element has a first anode, a light-emitting functional layer, and a first cathode stacked in sequence along a direction away from the array substrate. The photoelectric element is located on the array substrate and on a side of the light-emitting element. The photoelectric element is arranged corresponding to the second driving circuit. The photoelectric element has a second anode, a photosensitive layer, and a second cathode stacked in sequence along the direction away from the array substrate. The first cathode and the second cathode are in a same film layer. The first cathode is not in contact with the second cathode.

### CROSS-REFERENCE TO RELATED APPLICATION

This application claims priority to Chinese Patent Application No. 202410519732.5, filed on Apr. 26, 2024, the entire content of which is incorporated herein by reference.

### TECHNICAL FIELD

The present disclosure relates to the field of display technology, and in particular, to a display panel and a display device.

### BACKGROUND

An independent photoelectric sensing element is adhered under a screen to realize a photoelectric sensing function such as fingerprint recognition. This makes the overall thickness of the display screen to be large, affecting the design of an entire device structure and increasing the production cost of the product.

### SUMMARY

One aspect of the present disclosure provides a display panel. The display panel includes an array substrate, a light-emitting element, and a photoelectric element. The array substrate has a first driving circuit and a second driving circuit, arranged at intervals. The light-emitting element, on the array substrate, is arranged corresponding to the first driving circuit. The light-emitting element has a first anode, a light-emitting functional layer, and a first cathode stacked in sequence along a direction away from the array substrate. The photoelectric element is located on the array substrate and on a side of the light-emitting element. The photoelectric element is arranged corresponding to the second driving circuit. The photoelectric element has a second anode, a photosensitive layer, and a second cathode stacked in sequence along the direction away from the array substrate. The first cathode and the second cathode are in a same film layer. The first cathode is not in contact with the second cathode.

Another aspect of the present disclosure provides a display device that has a display panel. The display panel includes an array substrate, a light-emitting element, and a photoelectric element. The array substrate has a first driving circuit and a second driving circuit, arranged at intervals. The light-emitting element, on the array substrate, is arranged corresponding to the first driving circuit. The light-emitting element has a first anode, a light-emitting functional layer, and a first cathode stacked in sequence along a direction away from the array substrate. The photoelectric element is located on the array substrate and on a side of the light-emitting element. The photoelectric element is arranged corresponding to the second driving circuit. The photoelectric element has a second anode, a photosensitive layer, and a second cathode stacked in sequence along the direction away from the array substrate. The first cathode and the second cathode are in a same film layer. The first cathode is not in contact with the second cathode.

### BRIEF DESCRIPTION OF THE DRAWINGS

The drawings in the specification, which constitute a part of the present disclosure, are used to provide further understanding of the present disclosure. Embodiments of the present disclosure and their descriptions are used to explain the present disclosure and do not constitute improper limitations on the present disclosure.

FIG. 1 illustrates a schematic diagram showing a top view of one display panel according to various embodiments of the present disclosure.

FIG. 2 illustrates a schematic diagram of a cross-sectional structure along the BB′ direction in FIG. 1.

FIG. 3 illustrates a schematic diagram showing a top view of another display panel according to various embodiments of the present disclosure.

FIG. 4 illustrates a schematic diagram of a cross-sectional structure along the BB′ direction in FIG. 3.

FIG. 5 illustrates a schematic diagram showing a top view of another display panel according to various embodiments of the present disclosure.

FIG. 6 illustrates a schematic diagram of a cross-sectional structure along the BB′ direction in FIG. 5.

FIG. 7 illustrates a schematic diagram of light propagation of one display panel according to various embodiments of the present disclosure.

FIG. 8 illustrates a perspective view of one display panel from a top view angle according to various embodiments of the present disclosure.

FIG. 9 illustrates a perspective view of another display panel from a top view angle according to various embodiments of the present disclosure.

FIG. 10 illustrates a perspective view of another display panel from a top view angle according to various embodiments of the present disclosure.

FIG. 11 illustrates a perspective view of another display panel from a top view angle according to various embodiments of the present disclosure.

FIG. 12 illustrates a schematic structural diagram of one display device according to various embodiments of the present disclosure.

### DETAILED DESCRIPTION OF THE EMBODIMENTS

To help those persons of skilled in the art to better understand the present disclosure, a technical solution in embodiments of the present disclosure will be clearly and completely described below in conjunction with the drawings in embodiments of the present disclosure. Obviously, described embodiments are only part of embodiments of the present disclosure, not all embodiments. Based on embodiments of the present disclosure, all other embodiments obtained by those persons of skilled in the art without creative work should fall within the scope of protection of the present disclosure.

Moreover, words such as “first”, “second”, and similar words used in embodiments of the present disclosure do not indicate any order, quantity, or importance, but are only used to distinguish different components. Similarly, words such as “one”, “an”, or “the” do not indicate a quantity limitation, but indicate the existence of at least one. Words such as “include”, “comprise”, and similar words mean that elements or objects appearing before the words include elements or objects listed after the words and their equivalents, without excluding other elements or objects. Words such as “connect”, “connected”, and similar words are not limited to physical or mechanical connections, but may include electrical connections, whether direct or indirect. “Up”, “down”, “left”, “right”, and the like are only used to indicate relative positional relationships. When an absolute position of the described object changes, the relative positional relationship may also change accordingly. In addition, the descriptions of “same” and “equal” in embodiments of the present disclosure do not mean that two objects are completely equal in size or shape. They are allowed to be roughly the same or roughly equal within a certain error range.

It should be noted that an implementation method provided in embodiments of the present disclosure can be combined with each other if there is no contradiction.

A display screen with a photoelectric sensing function, such as a display screen with a fingerprint recognition function, is relatively thick, resulting in a large overall thickness of the display device, making it difficult to achieve a light and thin design. In order to address the issue, embodiments of the present disclosure provide a display panel and a display device.

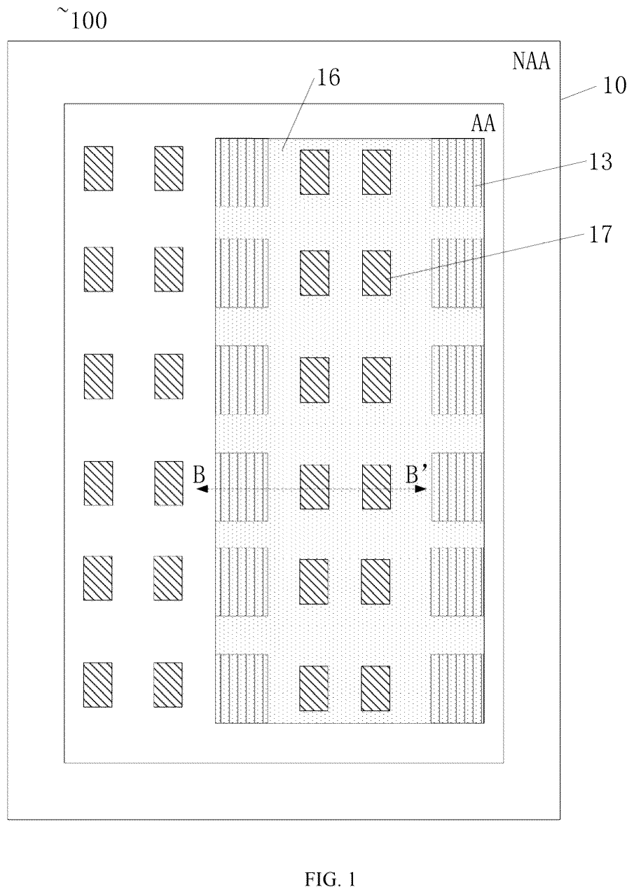

FIG. 1 is a schematic diagram of a top view of a display panel provided in embodiments of the present disclosure. As shown in FIG. 1, the display panel includes an array substrate 10. The array substrate 10 includes a display area AA and a non-display area NAA surrounding the display area AA. The display panel also includes a plurality of light-emitting elements 13 and a plurality of photoelectric elements 17 located in the display area AA of the array substrate 10. FIG. 1 exemplarily shows an arrangement in which one side of each photoelectric element 17 is a photoelectric element 17 and the other side of each photoelectric element 17 is a light-emitting element 13. However, the arrangement of the light-emitting element 13 and the photoelectric element 17 is not limited thereto. In addition, in FIG. 1, the light-emitting element 13 and the photoelectric element 17 are arranged in a matrix pattern. However, the arrangement pattern of the light-emitting element 13 and the photoelectric element 17 are not limited to the matrix pattern.

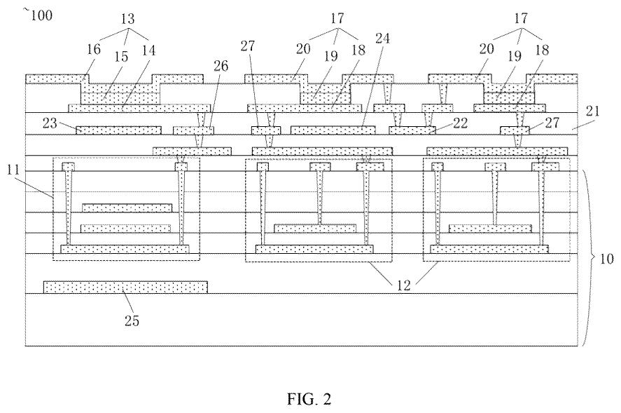

The display panel 100 is now described in more detail with reference to FIG. 2, which is a schematic diagram of a cross-sectional structural along the BB′ direction in FIG. 1. Referring to FIG. 2, the display panel 100 specifically includes below elements.

The array substrate 10 includes a first driving circuit 11 and a second driving circuit 12 which are arranged at intervals.

A light-emitting element 13 is located on the array substrate 10. The light emitting element 13 is arranged corresponding to the first driving circuit 11. The light emitting element 13 includes a first anode 14, a light-emitting functional layer 15, and a first cathode 16, which are sequentially stacked in a direction away from the array substrate 10.

Specifically, the corresponding setting may be a one-to-one connection between the light-emitting element and the first driving circuit, or a corresponding connection between the plurality of light-emitting elements and one first driving circuit. Of course, the light-emitting element and the first driving circuit may also be multiple-to-one setting. The first driving circuit is used to drive a corresponding light-emitting element to emit light to form an image to be displayed by the display panel. The first cathode is arranged in correspondence with the display area of the display panel, and is used to receive and transmit energy and a control signal. Generally, the first cathode is formed of a material with a high transmittance so that it does not affect the normal display light emission. For example, the first cathode can be a metal electrode or a metal oxide electrode.

The photoelectric element 17 is located on the array substrate 10 and is located on a side of the light-emitting element 13 along a direction perpendicular to a direction away from the array substrate 10. The photoelectric element 17 is arranged corresponding to a second driving circuit 12. The photoelectric element 17 includes a second anode 18, a photosensitive layer 19, and a second cathode 20, stacked in sequence along the direction away from the array substrate 10. The first cathode 16 and the second cathode 20 are in a same film layer. The first cathode 16 and the second cathode 20 are not in contact.

Specifically, the photoelectric element is an element that provides a photoelectric conversion function, such as fingerprint recognition, ambient light detection, and other functions. The corresponding arrangement can be a one-to-one connection between the photoelectric element and the second driving circuit. Alternatively, a plurality of photoelectric elements can be connected to one second driving circuit. The second driving circuit is used to drive a corresponding photoelectric element to achieve the photoelectric conversion function. The second cathode is arranged corresponding to the display area of the display panel, and is used to receive and transmit energy and control a signal. Generally, a material with a high transmittance is used to make the second cathode so that it does not affect the normal display light emission. For example, the second cathode can be a metal electrode or a metal oxide electrode. Voltage signals received and transmitted by the first cathode and the second cathode are different, so the first cathode and the second cathode are not in contact. The materials used to make the first cathode and the second cathode can be the same or different.

By embodiments of the present disclosure, the light-emitting element and the photoelectric element are both arranged on the array substrate. A cathode of the light-emitting element and a cathode of the photoelectric element are arranged on a same layer. The cathode of the light-emitting element and the cathode of the photoelectric element are not in contact, so that the cathode of the light-emitting element and the cathode of the photoelectric element can realize the transmission of electrical signals of different voltages. In this way, without affecting the actual function and the photoelectric conversion function, the light-emitting element and the photoelectric element are highly integrated. When an independent photoelectric sensing element is adhered under the screen to realize the photoelectric sensing function such as fingerprint recognition, it causes a technical issue of a large thickness of the display panel. Thus, the present disclosure reduces the thickness of the display panel, which is conducive to realizing a light and thin design of the display panel.

In practical application, the first cathode of the light-emitting element is generally arranged on an entire surface, and there is an issue of insufficient space utilization. The present disclosure uses one functional layer, originally used to dispose the first cathode on the entire surface, to arrange the first cathode and the second cathode. This fully utilizes the space of the functional layer of the display panel and increases the integration of the light-emitting element and the photoelectric element.

Specifically, the light-emitting element includes at least one of the following: a visible light-emitting element and an invisible light-emitting element. In embodiments of the present disclosure, the light-emitting element is specifically an OLED.

To ensure that the display panel has a good display and light-emitting effect, in an optional solution of the present disclosure, transmittances of the first cathode and the second cathode are higher than 45% respectively. The transmittance of the first cathode is relatively higher, and the light emitted by the light-emitting functional layer can basically be normally transmitted. Thus, the first cathode can avoid blocking the normal light-emission of the light-emitting functional layer, thereby further ensuring the normal display effect of the display panel. At the same time, the transmittance of the second cathode is also relatively high, and the reflected light can enter a photoelectric sensing layer normally, thereby further ensuring the normal sensing operation of the photoelectric sensing layer.

In a specific application process, an anode of the light-emitting element and an anode of the photoelectric element can be arranged in different functional layers, or can be arranged in a same layer. The light-emitting functional layer of the light-emitting element and the photosensitive layer of the photoelectric element can be arranged in different functional layers, or can be arranged a same layer. According to another optional embodiment of the present disclosure, the first anode and the second anode are in a same film layer, and the light-emitting functional layer and the photosensitive layer are in a same film layer. In this embodiment, as shown in FIG. 2, the first anode 14 and the second anode 18 share a layer, and the light-emitting functional layer 15 and the photosensitive layer 19 share a layer. In this way, there is no need to arrange a separate film layer for the photoelectric element to arrange the second anode or arrange a separate film layer for the photosensitive layer. This further increases the utilization percentage of space of the film layer in the display panel, and further realizes a high integration of the light-emitting element and the photoelectric element. Thus, this further ensures that the overall thickness of the display panel is small, which is conducive to thinning the display panel.

In addition, compared with the technical approach in which the photosensitive layer and the light-emitting functional layer are arranged in different layers, as well as the photosensitive layer is lower than the light-emitting functional layer (i.e., a distance from the photosensitive layer to the array substrate is less than a distance from the light-emitting functional layer to the array substrate), the light-emitting functional layer and the photosensitive layer are arranged in a same layer in the present disclosure. This reduces a path length of the light reaching the photosensitive layer and enhances the intensity of the light signal received by the photosensitive layer. Specifically, when the photosensitive layer is used for fingerprint recognition, the light is the light emitted by the light-emitting functional layer and reflected from the finger. When the photosensitive layer is used for ambient light detection, the light is the ambient light irradiated into the display panel.

Furthermore, the first cathode and the second cathode are made of a same cathode layer, that is, the first cathode and the second cathode are two non-contact cathode structures generated by using the same material to form the cathode layer through a film growth process, and using a mask to pattern the cathode layer. In this way, there is no need to grow the film layers of the first cathode and the second cathode separately, nor to use two masks to pattern them, which simplifies the manufacturing process of the display panel and reduces the manufacturing cost of the display panel.

Similarly, the first anode and the second anode are made of a same anode layer, that is, the first anode and the second anode are two non-contact anode structures generated by using the same material to form the anode layer through a film growth process, and using a mask to pattern the anode layer. In this way, there is no need to grow the film layers of the first anode and the second anode separately, nor to use two masks to pattern them, which simplifies the manufacturing process of the display panel and reduces the manufacturing cost of the display panel.

Specifically, since the first cathode and the second cathode are manufactured by a same process, the first cathode and the second cathode have a same thickness. Similarly, since the first anode and the second anode are manufactured by the same process, the first anode and the second anode have the same thickness.

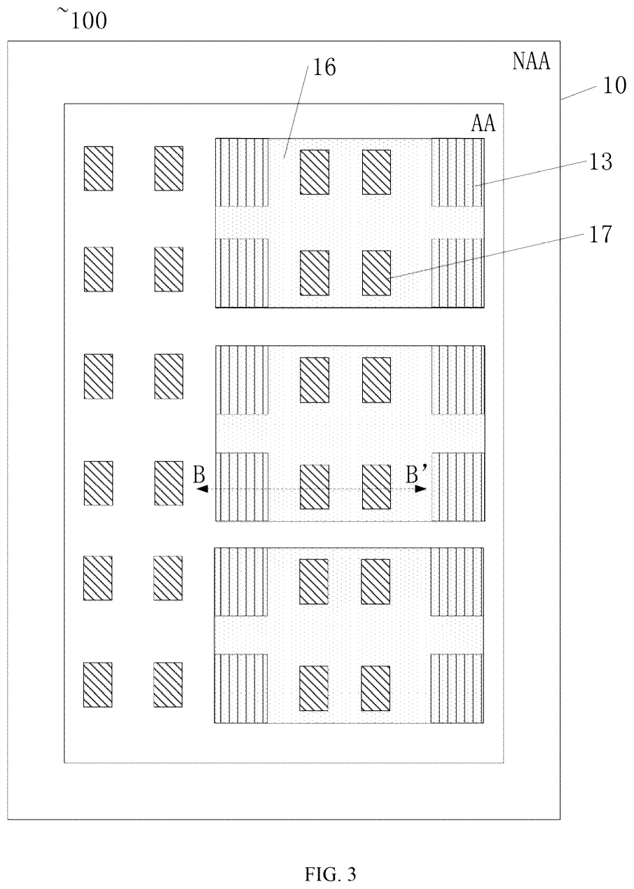

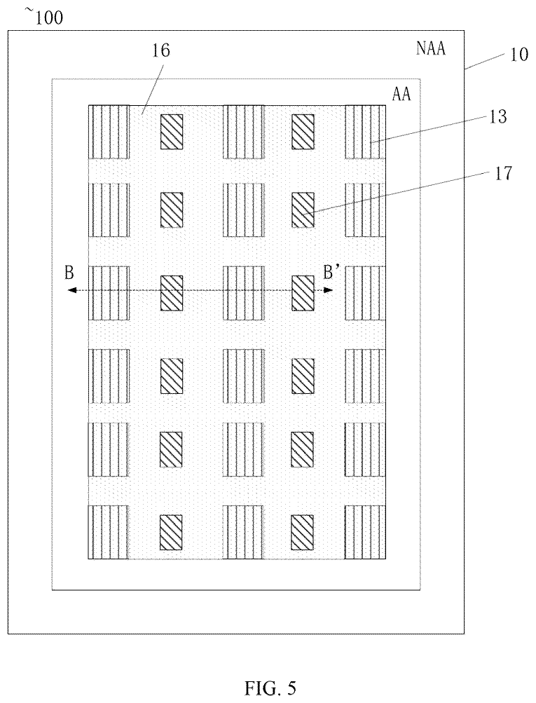

Optionally, as shown in FIG. 1, there are multiple light-emitting elements 13, and the multiple light-emitting elements 13 are arranged in a matrix. First cathodes 16 of the multiple light-emitting elements 13 are in contact. Among them, the first cathodes 16 of the multiple light-emitting elements 13 are in contact, which can be that the first cathodes 16 of all the light-emitting elements 13 are electrically connected as shown in FIG. 1 and FIG. 5, that is, cathodes of the light-emitting elements are wired on the entire surface. As shown in FIG. 3, first cathodes 16 of some of the light-emitting elements 13 are electrically connected, such as separating the light-emitting elements 13 into groups according to the distance. Each group includes at least two light-emitting elements 13, and the first cathodes 16 of the light-emitting elements 13 in the group are electrically connected.

Of course, the first cathode may not be electrically connected to other first cathodes. In one embodiment, any two first cathodes are not in contact. In another embodiment, among the plurality of first cathodes, some of the first cathodes are electrically connected, while some of the first cathodes are not electrically connected to other first cathodes.

Optionally, as shown in FIG. 1, there are multiple photoelectric elements 17, and the multiple photoelectric elements 17 are arranged in a matrix. Among the multiple photoelectric elements 17, second cathodes 20 of any two of the photoelectric elements 17 are not in contact (not shown in the figure). Alternatively, among the multiple photoelectric elements 17, the second cathodes 20 of at least some of the photoelectric elements 17 are in contact (not shown in the figure). Thus, the multiple second cathodes are connected in parallel. The multiple second cathodes in parallel can share a signal transmission line to realize signal transmission, thereby reducing the total number of signal transmission lines connected to the second cathodes in the display panel.

In another optional solution, as shown in FIG. 1, there are a plurality of the photoelectric elements 17, and the plurality of the photoelectric elements 17 are arranged in a matrix. As shown in FIG. 2, the display panel further includes: a first metal layer 21 that is located between the plurality of the photoelectric elements 17 and the array substrate 10. The first metal layer 21 includes a plurality of first metal wires 22. The first metal wires 22 are electrically connected to two adjacent second cathodes 20 arranged along a matrix row direction of the photoelectric element 17. In this embodiment, by forming the first metal layer between the array substrate and the photoelectric element as well as connecting the adjacent second cathodes along the matrix row direction through the first metal wires provided on the first metal layer. This achieves a flexible and independent wiring of the cathodes of the photoelectric elements.

There are multiple wiring methods for a first metal wire.

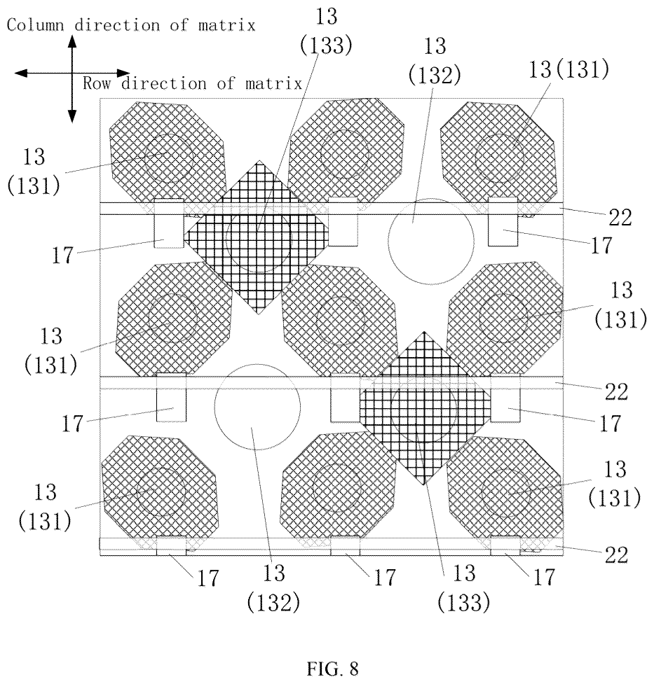

FIG. 8 shows a wiring method of a first metal wire in an embodiment of the present application. As shown in FIG. 8, there are a plurality of light-emitting elements 13. The plurality of light-emitting elements 13 are arranged in a matrix. The light-emitting element 13 and the photoelectric element 17 are arranged alternately and spaced apart. An orthographic projection of the first metal wire 22 on the array substrate 10 overlaps with an orthographic projection of the light-emitting functional layer 15 on the array substrate 10. That is, along the matrix row direction of the photoelectric element, the first metal wire connects two adjacent second cathodes by passing through a light-emitting sub-pixel.

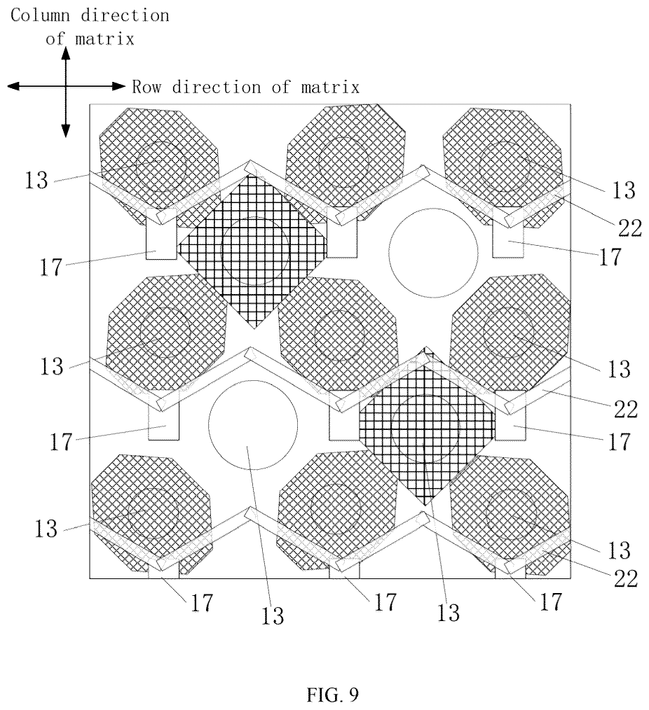

FIG. 9 shows another wiring method of the first metal wire in an embodiment of the present disclosure. As shown in FIG. 9, there are multiple light-emitting elements 13. The multiple light-emitting elements 13 are arranged in a matrix. The light-emitting element 13 and the photoelectric element 17 are arranged alternately and spaced apart. The orthographic projection of the first metal wire 22 on the array substrate 10 does not overlap with the orthographic projection of the light-emitting functional layer 15 on the array substrate 10. That is, along the matrix row direction of the photoelectric element, the first metal wire connects two adjacent second cathodes by bypassing the light-emitting sub-pixel.

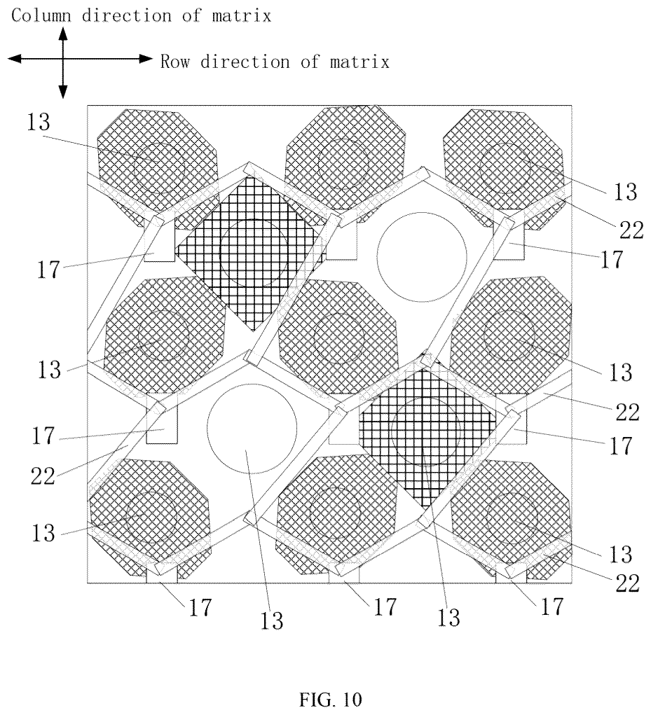

FIG. 10 shows another wiring method of the first metal wire in an embodiment of the present disclosure. As shown in FIG. 10, there are multiple light-emitting elements 13. The multiple light-emitting elements 13 are arranged in a matrix. The light-emitting element 13 and the photoelectric element 17 are arranged alternately and spaced apart. The first metal wire 22 is also electrically connected to two adjacent second cathodes arranged along the matrix column direction of the photoelectric elements 17, and the orthographic projection of the first metal wire 22 on the array substrate 10 does not overlap with the orthographic projection of the light-emitting functional layer 15 on the array substrate 10. In other words, the orthographic projection of the first metal wire 22, connected to the second cathode 20 arranged along the matrix row direction, on the array substrate 10 does not overlap with the orthographic projection of the light-emitting functional layer 15 on the array substrate 10. Furthermore, the orthographic projection of the first metal wire 22, connected to the second cathode 20 arranged along the matrix column direction, on the array substrate 10 does not overlap with the orthographic projection of the light-emitting functional layer 15 on the array substrate 10. In this embodiment, in the matrix row and matrix column directions of the photoelectric elements, the first metal wire is connected to two adjacent second cathodes by bypassing the light-emitting sub-pixel, thereby realizing a wiring method that winds around the periphery of the light-emitting sub-pixel.

Of course, according to different design requirements, those persons of skilled in the art can also make changes and adjustments based on the three wiring methods to achieve other wiring methods, and these adjusted wiring methods are all within the scope of protection demonstrated in the present disclosure.

It should be noted that FIG. 8 is only an exemplary perspective schematic diagram of a display panel from a top view. There are three types of light-emitting elements 13, namely, a green light-emitting element 131, a blue light-emitting element 132, and a red light-emitting element 133. Of course, the light-emitting elements are not limited to the three types, and may also be light-emitting elements of only one color, or light-emitting elements of multiple colors.

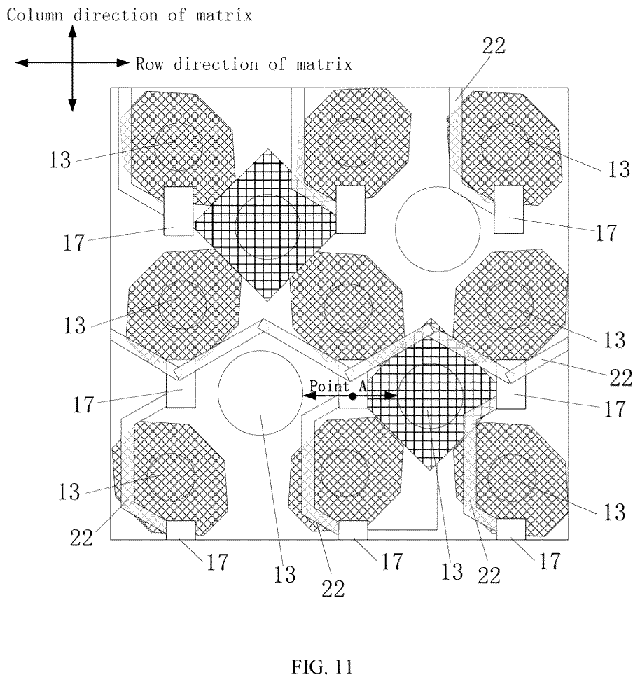

As shown in FIG. 11, an orthographic projection of point A, the midpoint of the shortest line between two adjacent light-emitting functional layers 15, on the array substrate 10 is the first projection. An orthographic projection of the photosensitive layer 19 located between the two adjacent light-emitting functional layers 15 on the array substrate 10 is the second projection. The first projection is in the second projection. The two adjacent light-emitting functional layers are respectively referred to as the first light-emitting functional layer and the second light-emitting functional layer. The shortest line refers to a line connecting a surface of the first light-emitting functional layer, close to the second light-emitting functional layer, to a surface of the second light-emitting functional layer, close to the first light-emitting functional layer. In the display panel, a specific area of the photosensitive layer needs to be calculated based on the amount of interference light reflected inside the light-emitting functional layer. In order to further ensure that the photoelectric element can accurately perform fingerprint recognition or ambient light detection functions, it is necessary to ensure that the midpoint of the shortest line overlaps with the projection of the photosensitive layer.

Optionally, as shown in FIG. 2, the first metal layer 21 further includes at least one of the following elements.

A first light-shielding structure 23 is located at one side of the first metal wire 22 while not in contact with the first metal wire 22. An orthographic projection of the first light-shielding structure 23 on the array substrate 10 overlaps with a first driving circuit 11.

A second light-shielding structure 24 is located at one side of the first metal wire 22 while not in contact the first metal wire 22. An orthographic projection of the second light-shielding structure 24 on the array substrate 10 overlaps with a second driving circuit 12.

The first light-shielding structure corresponding to the first driving circuit is provided in the first metal layer to shield the first driving circuit, which can reduce the performance fluctuation of the first driving circuit caused by light. This achieves the noise reduction function and reduces the reflection issue of the first driving circuit. Similarly, the second light-shielding structure corresponding to the second driving circuit is provided in the first metal layer to shield the second driving circuit, which can reduce the performance fluctuation of the second driving circuit caused by light. This achieves the noise reduction function and reduces the reflection issue of the second driving circuit.

In addition, the first light-shielding structure and the second light-shielding structure of the present disclosure are not in contact with the first metal wire and do not carry signals, thereby preventing the first light-shielding structure and the second light-shielding structure from generating parasitic capacitance with upper and lower layers.

As shown in FIG. 2, the array substrate further includes a third light-shielding structure 25. The third light-shielding structure 25 is located on a side of the first driving circuit 11 away from the light emitting element 13, and/or located on a side of the second driving circuit 12 away from the photoelectric element 17. In the present disclosure, since the first driving circuit and the second driving circuit may be exposed to ambient light, an issue of light leakage current may occur. By setting the third light-shielding structure, the external ambient light may be shielded from irradiating the first driving circuit and the second driving circuit, thereby avoiding the issue of light leakage current.

Specifically, the first light-shielding structure, the second light-shielding structure, and the third light-shielding structure can select a same light-shielding material. The same light-shielding material forms a light-shielding layer through a same process, and then form the first light-shielding structure, the second light-shielding structure, and the third light-shielding structure separately through patterning. This can further simplify the manufacturing process of the display panel and reduce the manufacturing cost.

In some embodiments of the present disclosure, as shown in FIG. 2, the first metal layer 21 further includes second metal wires 26 and a plurality of third metal wires 27 arranged at intervals. The first anode 14 is electrically connected to the first driving circuit 11 through a second metal wire 26, and the second anode 18 is electrically connected to the second driving circuit 12 through a third metal wire 27. The electrical connection between the light-emitting element and the corresponding driving circuit is realized through the second metal wire and the third metal wire.

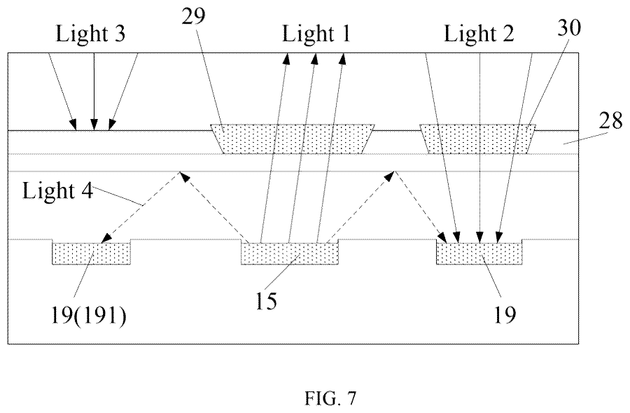

In addition, as shown in FIG. 7, the display panel also includes a light-shielding layer 28, which is located on a side of the light-emitting element 13 and the photoelectric element 17 away from the array substrate 10. The light-shielding layer 28 includes a first filter part 29 and at least one second filter part 30 that are arranged at intervals. The orthographic projection of the light-emitting functional layer 15 on the array substrate 10 is in an orthographic projection of the first filter part 29 on the array substrate 10, that is, the first filter part is located directly above the light-emitting functional layer. An orthographic projection area of the first filter part 29 on the array substrate 10 is larger than an orthographic projection area of the light-emitting functional layer 15 on the array substrate 10. An orthographic projection of at least one second filter part 30 on the array substrate 10 is in the orthographic projection of the photosensitive layer 19 on the array substrate 10, that is, the second filter part is located directly above the photosensitive layer. An orthographic projection area of the second filter part 30 on the array substrate 10 is smaller than an orthographic projection area of the photosensitive layer 19 on the array substrate 10. In some embodiments, the light with a demanded radiation wavelength (i.e., light 2 in FIG. 7) is selected by the second filter part located above the photosensitive layer. Thus, the light can smoothly reach the photosensitive layer, realizing light sensing and photoelectric conversion as well as a corresponding function. The light with a required radiation wavelength (i.e., light 1 in FIG. 7) is selected and emitted through the first filter part located above the light-emitting functional layer to realize the normal display function.

Specifically, as shown in FIG. 7, there are a plurality of the photoelectric elements 17, a plurality of the second filter parts 30. The plurality of the second filter parts 30 are arranged at intervals. An orthographic projection of at least one of the photosensitive layers 19 on the array substrate 10 does not overlap with an orthographic projection of any of the second filter parts 30 on the array substrate 10. The photosensitive layer 19 that does not overlap with orthographic projections of all the second filter parts 30 on the array substrate 10 is called a correction photosensitive layer 191, such as the correction photosensitive layer 191 on the far left of FIG. 7. A portion of the light emitted by the light-emitting functional layer (i.e., light 1 in FIG. 7) is emitted through the first filter part. Another portion of the light (i.e., light 4 in FIG. 7) is propagated inside the display panel through reflection and other channels, which will interfere with the normal photoelectric sensing of the photosensitive layer. The correction photosensitive layer of the present disclosure is used to detect this portion of the interference light, to facilitate the correction of the light data of the photosensitive layer which has the second filter part arranged directly above. This further ensures the detection accuracy of the photoelectric element.

Furthermore, as shown in FIG. 7, the second filter part 30 is not provided directly above the correction photosensitive layer 191. Thus, the external light (i.e., the light 3 in FIG. 7) cannot reach the correction photosensitive layer 191, further ensuring that the light data detected by the correction filter part is only the light (i.e., the light 4) reflected from the light-emitting functional layer 15 by an inner film layer of the display panel.

In the display panel of the present disclosure, the photoelectric element can be used for fingerprint signal collection, that is, the display panel is a display screen integrated with the fingerprint recognition function. In addition to the fingerprint recognition function, the photoelectric element can also be used for ambient light signal collection, that is, the display panel is an ambient light collection device. Of course, the fingerprint recognition function and the ambient light detection function can also be integrated in one display panel. In the scenario the photoelectric element is used for fingerprint signal collection, the second filter part includes a green filter part. When the photoelectric element is used for fingerprint recognition, the light-emitting functional layer serves as a light-emitting part. The photosensitive layer serves as a light-receiving unit. The light with the demanded radiation wavelength is selected through the second filter part located above the photosensitive layer. Thus, the light reaches the photosensitive layer smoothly to realize fingerprint recognition. The light with the demanded radiation wavelength is generally a green light. In the case the photoelectric element is an ambient light signal collection element, the color of the light that can pass through the second filter part is the same as the color of the ambient light. When it is necessary to detect red ambient light, the second filter part is a red filter part. When it is necessary to detect blue ambient light, the second filter part is a blue filter part. When it is necessary to detect green ambient light, the second filter part is a green filter part.

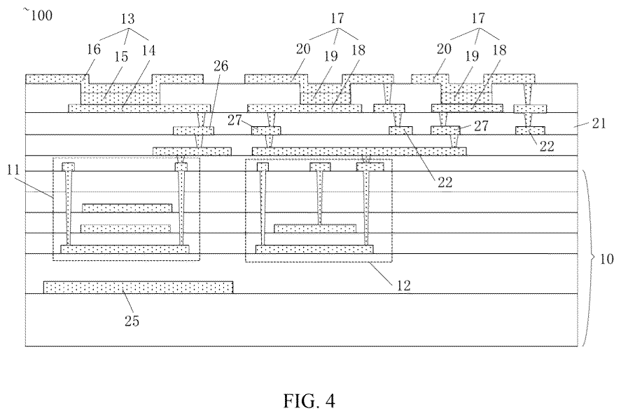

FIG. 3 is a schematic diagram of a top view of another display panel provided by an embodiment of the present disclosure. FIG. 4 is a schematic diagram of a cross-sectional structure along the BB′ direction in FIG. 2. As shown in FIG. 4, a plurality of the photoelectric elements 17 corresponds to one second driving circuit 12. The method of using one second driving circuit to drive a plurality of photoelectric elements can reduce the total number of second driving circuits. Moreover, a plurality of photoelectric elements can be connected in parallel through a shared second driving circuit, thereby further realizing the miniaturization of the display panel.

Except for the above differences, other structures in FIG. 4 may be same as or different from the structure shown in FIG. 2.

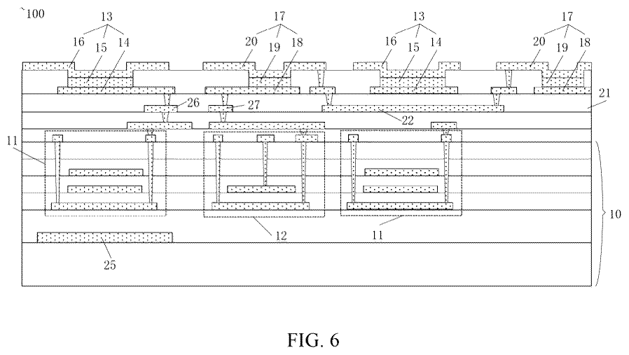

FIG. 5 is a schematic diagram of a top view of another display panel provided by an embodiment of the present disclosure. FIG. 6 is a schematic diagram of a cross-sectional structure along the BB′ direction in FIG. 5. As shown in FIG. 6, the light-emitting element 13 and the photoelectric element 17 are alternately arranged. The light-emitting element 13 are connected to the first driving circuit 11 in a one-to-one correspondence. The plurality of photoelectric elements is connected to one of the second driving circuits 12. In addition, second cathodes 20 of the plurality of photoelectric elements 17 are electrically connected through the first metal wire 22.

Except for the above differences, other structures in FIG. 6 may be same as or different from the structure shown in FIG. 2.

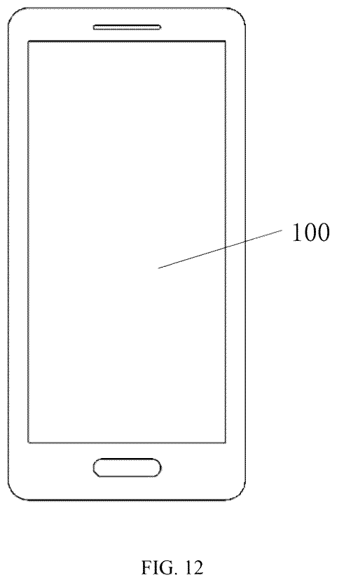

According to another aspect of the present disclosure, a display device as shown in FIG. 12 is also provided. The display device includes any one of the display panels 100 described above.

The display device includes any one of the display panels described above, and the display panel arranges the light-emitting element and the photoelectric element on the array substrate. The cathode of the light-emitting element and the cathode of the photoelectric element are arranged in the same layer, and the two are not in contact. Thus, the cathode of the light-emitting element and the cathode of the photoelectric element can realize the transmission of electrical signals of different voltages. In this way, a high degree of integration of light-emitting element and photoelectric element is achieved without affecting actual functions and photoelectric conversion functions. Using an independent photoelectric sensing element adhered under the screen to achieve a photoelectric sensing function such as fingerprint recognition causes the technical issue of a large thickness of the display panel. The present disclosure reduces the thickness of the display panel, which is conducive to realizing a light and thin design of the display panel.

In embodiments of the present disclosure, the description of each embodiment has its own emphasis. For parts that are not described in detail in a specific embodiment, reference can be made to the relevant descriptions of other embodiments.

In the several embodiments provided in the present disclosure, the disclosed technical content can be implemented in other ways. Among them, device embodiments described above are only schematic. For example, the division of the units can be a logical function division. There may be other division methods in actual implementation. For example, multiple units or components can be combined or integrated into another system, or some features can be ignored or not executed. Another point is that the mutual coupling or direct coupling or communication connection shown or discussed can be through some interfaces, indirect coupling, or communication connection of units or modules, which can be electrical or other forms.

The units described as separate components may or may not be physically separated, and the components shown as units may or may not be physical units, that is, they may be in one place or distributed on multiple units. Some or all the units may be selected according to actual needs to achieve the purpose of the present embodiment.

It should also be noted that the terms “include”, “comprises”, or any other variations thereof are intended to cover non-exclusive inclusion, so that a process, a method, a commodity, or a device including a series of elements include not only those elements, but also other elements not explicitly listed, or also include elements inherent to such process, method, commodity, or device. In the absence of more restrictions, the elements defined by the sentence “comprises a . . . ” do not exclude the existence of other identical elements in the process, the method, the commodity, or the device including the elements.

From the above description, embodiments described in the present disclosure achieve the following technical effects.

The display panel of the present disclosure arranges both the light-emitting element and the photoelectric element on the array substrate. The cathode of the light-emitting element and the cathode of the photoelectric element are arranged on the same layer, and the two are not in contact. Thus, the cathode of the light-emitting element and the cathode of the photoelectric element can realize the transmission of electrical signals of different voltages. In this way, a high degree of integration of light-emitting element and optoelectronic element is achieved without affecting actual functions and photoelectric conversion functions. Using an independent photoelectric sensing element adhered under the screen to achieve photoelectric sensing functions such as fingerprint recognition, which causes the technical issue of a large thickness of the display panel, the present disclosure reduces the thickness of the display panel, which is conducive to realizing a light and thin design of the display panel.

The above description is only preferred embodiments of the present disclosure and is not intended to limit the present disclosure. For those persons of skilled in the art, the present disclosure may have various modifications and variations. Any modification, equivalent replacement, improvement, etc. made within the spirit and principle of the present disclosure shall be included in the protection scope of the present disclosure.

What is claimed is:

1. A display panel, comprising
an array substrate comprising a first driving circuit and a second driving circuit; and the first driving circuit and the second driving circuit being arranged at intervals;
a light-emitting element, located on the array substrate; the light-emitting element being arranged corresponding to the first driving circuit; and the light-emitting element comprising a first anode, a light-emitting functional layer, and a first cathode stacked in sequence along a direction away from the array substrate; and
a photoelectric element, located on the array substrate and on a side of the light-emitting element; the photoelectric element being arranged corresponding to the second driving circuit; the photoelectric element comprising a second anode, a photosensitive layer, and a second cathode stacked in sequence along the direction away from the array substrate; the first cathode and the second cathode being located in a same film layer; and the first cathode being not in contact with the second cathode.

2. The display panel according to claim 1, wherein the first anode and the second anode are in a same film layer; and the light-emitting functional layer and the photosensitive layer are in a same film layer.

3. The display panel according to claim 1, wherein there are a plurality of light-emitting elements; the plurality of light-emitting elements is arranged in a matrix; and first cathodes of the plurality of light-emitting elements are in contact with each other.

4. The display panel according to claim 1, wherein there are a plurality of photoelectric elements; the plurality of photoelectric elements is arranged in a matrix; and any two second cathodes are not in contact, or second cathodes of at least some photoelectric elements are in contact.

5. The display panel according to claim 4, wherein the plurality of the photoelectric elements corresponds to one second driving circuit.

6. The display panel according to claim 1, wherein there are a plurality of photoelectric elements; the plurality of photoelectric elements is arranged in a matrix; and the display panel further comprises:
a first metal layer, located between the plurality of the photoelectric elements and the array substrate; the first metal layer comprising a plurality of first metal wires; a first metal wire of the plurality of first metal wires being electrically connected to two adjacent second cathodes; and the two adjacent second cathodes being arranged along a row direction of the matrix of the plurality of the photoelectric elements.

7. The display panel according to claim 6, wherein there are a plurality of light-emitting elements; the plurality of light-emitting elements is arranged in a matrix; the light-emitting element and the photoelectric element are arranged alternately at intervals; and an orthographic projection of the first metal wire on the array substrate overlaps with an orthographic projection of the light-emitting functional layer on the array substrate.

8. The display panel according to claim 7, wherein an orthographic projection of a midpoint of a shortest line between two adjacent light-emitting functional layers on the array substrate is a first projection; an orthographic projection of the photosensitive layer located between the two adjacent light-emitting functional layers on the array substrate is a second projection; and the first projection is in the second projection.

9. The display panel according to claim 6, wherein there are a plurality of light-emitting elements; the plurality of light-emitting elements is arranged in a matrix; the light-emitting element and the photoelectric element are arranged alternately at intervals; and the orthographic projection of the first metal wire on the array substrate does not overlap with the orthographic projection of the light-emitting functional layer on the array substrate.

10. The display panel according to claim 6, wherein there are a plurality of light-emitting elements; the plurality of light-emitting elements is arranged in a matrix; the light-emitting element and the photoelectric element are arranged alternately at intervals; the first metal wire is electrically connected to the two adjacent second cathodes; the two adjacent second cathodes are arranged along the row direction of the matrix of the plurality of the photoelectric elements; and the orthographic projection of the first metal wire on the array substrate does not overlap with the orthographic projection of the light-emitting functional layer on the array substrate.

11. The display panel according to claim 6, wherein the first metal layer further comprises at least one of
a first light-shielding structure, located on a side of the first metal wire and not in contact with the first metal wire; an orthographic projection of the first light-shielding structure on the array substrate overlaps with the first driving circuit; and
a second light-shielding structure, located on the side of the first metal wire and not in contact with the first metal wire; an orthographic projection of the second light-shielding structure on the array substrate overlaps with the second driving circuit.

12. The display panel according to claim 6, wherein the first metal layer further comprises a second metal wire and a plurality of third metal wires that are arranged at intervals; the first anode is electrically connected to the first driving circuit through the second metal wire; and the second anode is electrically connected to the second driving circuit through a third metal wire of the plurality of third metal wires.

13. The display panel according to claim 1, further comprising:
a light-shielding layer, located on a side of the light-emitting element and the photoelectric element away from the array substrate; the light-shielding layer comprising a first filter part and at least one second filter part that are spaced apart; an orthographic projection of the light-emitting functional layer on the array substrate being located in an orthographic projection of the first filter part on the array substrate; an orthographic projection area of the first filter part on the array substrate being larger than an orthographic projection area of the light-emitting functional layer on the array substrate; an orthographic projection of at least one second filter part on the array substrate being located in an orthographic projection of the photosensitive layer on the array substrate; and an orthographic projection area of the second filter part on the array substrate being smaller than an orthographic projection area of the photosensitive layer on the array substrate.

14. The display panel according to claim 13, wherein there are a plurality of photoelectric elements and a plurality of second filter parts; the plurality of second filter parts is arranged at intervals; and an orthographic projection of at least one photosensitive layer on the array substrate does not overlap with an orthographic projection of any one second filter part on the array substrate.

15. The display panel according to claim 13, wherein the photoelectric element is a fingerprint signal collection element; and the second filter part comprises a green filter part.

16. The display panel according to claim 13, wherein the photoelectric element is an ambient light signal collection element; and a light that passes the second filter part has a same color as an ambient light.

17. The display panel according to claim 1, wherein the light-emitting element comprises at least one of a visible light-emitting element and an invisible light-emitting element.

18. The display panel according to claim 1, wherein transmittances of the first cathode and the second cathode are respectively greater than 45%.

19. The display panel according to claim 1, wherein the first cathode and the second cathode are made of a same cathode layer; and the first anode and the second anode are made of a same anode layer.

20. A display device, comprising:
a display panel, comprising:
an array substrate comprising a first driving circuit and a second driving circuit; and the first driving circuit and the second driving circuit being arranged at intervals;
a light-emitting element, located on the array substrate; the light-emitting element being arranged corresponding to the first driving circuit; and the light-emitting element comprising a first anode, a light-emitting functional layer, and a first cathode stacked in sequence along a direction away from the array substrate; and
a photoelectric element, located on the array substrate and on a side of the light-emitting element; the photoelectric element being arranged corresponding to the second driving circuit; the photoelectric element comprising a second anode, a photosensitive layer, and a second cathode stacked in sequence along the direction away from the array substrate; the first cathode and the second cathode being located in a same film layer; and the first cathode being not in contact with the second cathode.
